(19) United States
(12) Patent Application Publication
(10) Pub. No.: US 2026/0362633 A1
(43) Pub. Date: Nov. 12, 2026

(54) PANEL STRUCTURE OF COMPUTER CASE

(71) Applicant: Chien-Hao CHEN, Keelung City (TW)

(72) Inventor: Chien-Hao CHEN, Keelung City (TW)

(21) Appl. No.: 19/444,851

(22) Filed: Jan. 9, 2026

(30) Foreign Application Priority Data
May 7, 2025 (TW) 114117220

(51) Int. Cl. H05K 7/20; G06F 1/20; H05K 5/02; H05K 5/03

(52) U.S. Cl. CPC H05K 7/20172; G06F 1/20; H05K 5/0221; H05K 5/0243; H05K 5/03; G06F 2200/201

(57) ABSTRACT

A front panel structure of a computer case is provided. The front panel structure comprises a panel body, a plurality of covers, and a plurality of cooling fans The panel body has an outer surface and an inner surface and is provided with a plurality of through holes, and each through hole penetrates the outer and inner surfaces of the panel body. Each cover is detachably connected to a corresponding through hole on the outer surface of the panel body to close the through hole, and each cover is provided with a plurality of ventilation holes. The cooling fans are sequentially located on the inner surface of the panel body, and each cooling fan is aligned opposite each of the through holes, such that airflow generated by the cooling fan after starting can flows in and out through the through holes and the covers.

### FIELD OF THE INVENTION

The present invention is related to a front panel structure of a computer case that features a simple structure, low cost, easy assembly, and improved internal heat dissipation efficiency, particularly suitable for use in desktop computers.

### BACKGROUND OF THE INVENTION

In recent years, computer devices have evolved at a rapid pace. As technology advances, their applications are ubiquitous, giving rise to what we now call computers. Computers have a variety of executive, computing functions to meet people's needs. Personal computers serve entertainment, word processing, and media playback functions in household settings. Industrial computers provide control, monitoring, and computational services for factory operations. Automotive computers offer multimedia entertainment for drivers and passengers, along with real-time information reception. Overall, computers have become indispensable devices in human society.

Existing computers and servers utilize chassis to accommodate electronic components, and computers or CPUs or graphics cards would generate waste heat during operation. Although high-performance or high-end CPUs and graphics cards are equipped with cooling devices such as heat sinks or fans to dissipate heat, there is still a risk of thermal shutdowns or component damage if the temperature inside the chassis is not expelled effectively.

Currently, the existing solutions involve adding external cooling devices to the chassis to draw in external cool air and direct it toward internal heat sources. However, existing cooling fans are typically fixed to the rear of the chassis, limiting their heat dissipation effectiveness.

### SUMMARY OF THE INVENTION

The primary object of the present invention is to provide a front panel structure of a computer case that is simple in design, low in cost, easy to assemble, and enhances internal heat dissipation efficiency in the computer case.

In order to achieve the object of the invention, the present invention provides a front panel structure of a computer case configured to be assembled and integrated with a front side of the computer case to form a computer case structure. The front panel structure comprises a panel body, a plurality of covers, and a plurality of cooling fans. The panel body has an outer surface and an inner surface, and the panel body is provided with a plurality of through holes, and each through hole penetrates the outer surface and the inner surface of the panel body. Each cover is detachably connected to a corresponding through hole on the outer surface of the panel body and mounted thereon to close the through hole, and each cover is provided with a plurality of ventilation holes. The cooling fans are sequentially located on the inner surface of the panel body, and each cooling fan is aligned opposite each of the through holes, such that airflow generated by the cooling fan after starting can flows in and out through the through holes and the covers.

In implementation, each through hole is provided with at least one engaging portion, and each cover is provided with a corresponding engaging portion capable of correspondingly engaging the engaging portion, thereby enabling each cover to be detachably and securely mounted to the outer surface of the panel body.

In implementation, the engaging portion is a protrusion on an inner wall of the through hole, and the corresponding engaging portion is an L-shaped engaging slot disposed in the cover.

In implementation , the front panel structure further comprises an inner frame having an inner side and an outer side, wherein the outer side of the inner frame is configured to engage with the inner surface of the panel body, and the inner side of the inner frame is configured to engage with the computer case, each cooling fan is sequentially positioned between the outer side of the inner frame and the inner surface of the panel body, and each cooling fan is respectively aligned opposite each of the through holes, enabling the airflow generated by the cooling fan after starting to flow in and out through the through holes.

In implementation, the inner frame is provided with a plurality of lock holes for securing the cooling fan to the outer side of the inner frame via a locking connection.

In implementation, the panel body is a light-transmissive panel body.

In implementation, the panel body is a mirror-finish panel body.

For further understanding the characteristics and effects of the present invention, some preferred embodiments referred to drawings are in detail described as follows.

### BRIEF DESCRIPTION OF DRAWINGS

FIG. 1 is a schematic diagram illustrating the state of the front panel structure and the computer case prior to assembly in an embodiment of the present invention.

FIG. 2 is an exploded perspective view of the front panel structure of the computer case in an embodiment of the present invention.

FIG. 3 is a schematic diagram illustrating the state of the cover and the panel body prior to assembly in an embodiment of the present invention.

FIG. 4 is a schematic diagram illustrating the state of the front panel structure and the computer case after assembly in an embodiment of the present invention.

FIG. 5 is a front view of the front panel structure and the computer case after assembly in an embodiment of the present invention.

### DETAILED DESCRIPTION OF PREFERRED EMBODIMENTS

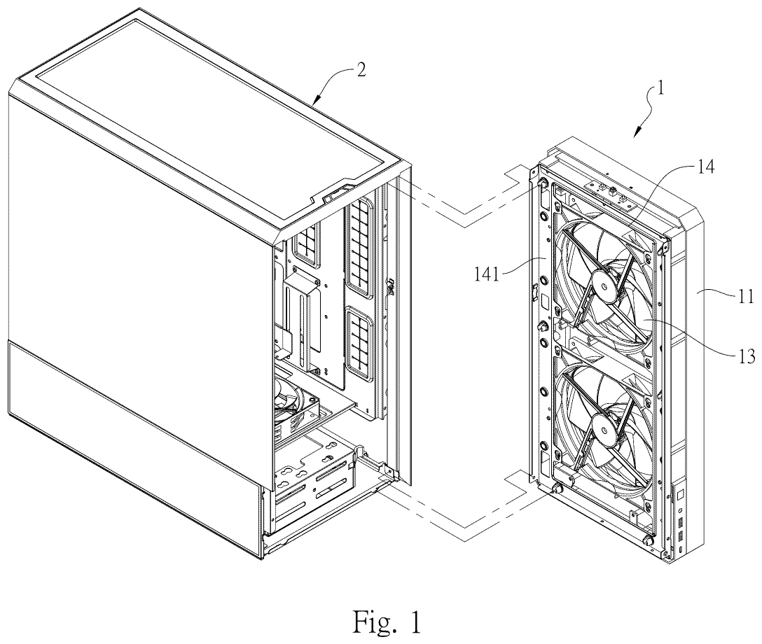

With reference to FIGS. 1 to 5, a front panel structure 1 of a computer case 2 according to an embodiment of the present invention is configured to be assembled and integrated with a front side of the computer case 2 to form a computer case structure. The front panel structure 1 of the computer case 2 mainly consists of a panel body 11, a plurality of covers 12, and a plurality of cooling fans 13.

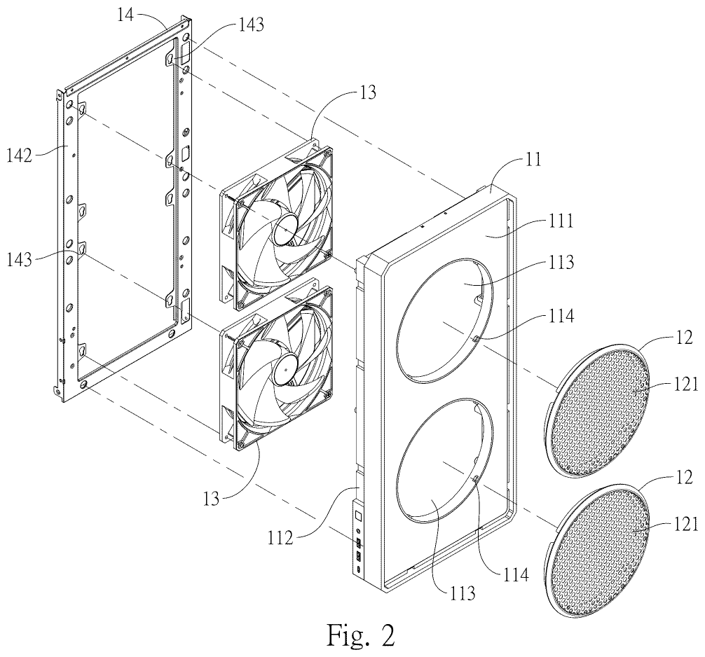

As shown in FIGS. 1 and 2, the panel body 11 could be a light-transmissive or a mirror-finish panel body 11, such as a glass panel or an acrylic panel. The panel body 11 has an outer surface 111 and an inner surface 112, and is provided with a plurality of through holes 113, and each through hole 113 penetrates the outer surface 111 and the inner surface 112 of the panel body 11. Each cover 12 is detachably and sequentially connected to a corresponding through hole 113 on the outer surface 111 of the panel body 12 and mounted thereon to close each of the through holes 113. Each cover 12 is disposed with a plurality of ventilation holes 112, and each of the cooling fans 13 is sequentially located on the inner surface 112 of the panel body 11 and aligned opposite each of the through holes 113.

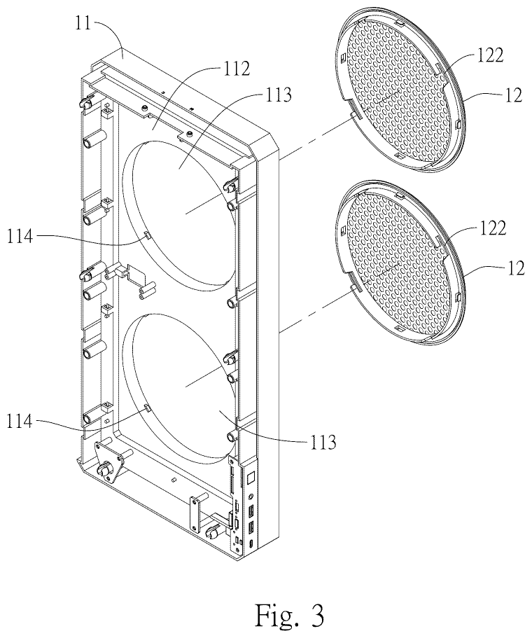

In the design of the panel body 11 of this embodiment, each through hole 113 is disposed with at least one engaging portion 114, and each cover 12 is disposed with a corresponding engaging portion 122 capable of correspondingly engaging the engaging portion 14. The engaging portion 114 is a protrusion on an inner wall of the through hole 113 (as shown in FIGS. 2 and 3), and the corresponding engaging portion 122 is an L-shaped engaging slot disposed in the cover 12 (as shown in FIG. 3), thereby enabling each cover 12 to be detachably and securely mounted to the outer surface 111 of the panel body 11. Certainly, the coupling method for these portions is not limited to the aforementioned rotational snap-fit coupling. For example, by providing mutually magnetic materials on both the through hole 113 and the cover 12, or through other mutually engaging mechanical designs, the objective of allowing the cover 12 to be detachably and securely coupled to the outer surface 111 of the panel body 11 can also be achieved.

Additionally, as shown in FIGS. 1 to 3, the front panel structure 1 of the computer case 2 further comprises an inner frame 14, and the inner frame 14 has an inner side 141 and an outer side 142. The outer side 141 of the inner frame 14 is configured to engage with the inner surface 112 of the panel body 11, and the inner side 141 of the inner frame 14 is configured to engage with the computer case 2 (as shown in FIG. 1). Each of the cooling fans 13 is sequentially positioned between the outer side 142 of the inner frame 14 and the inner surface 112 of the panel body 11, and each of the cooling fan 13 is respectively aligned opposite each of the through holes 113, thereby when the cooling fans 13 start up, the airflow generated by the cooling fans 13 could flow in and out through the through holes 113. Furthermore, the inner frame 14 is provided with a plurality of lock holes 143 for securing the cooling fans 13 to the outer side 142 of the inner frame 14 via a locking connection.

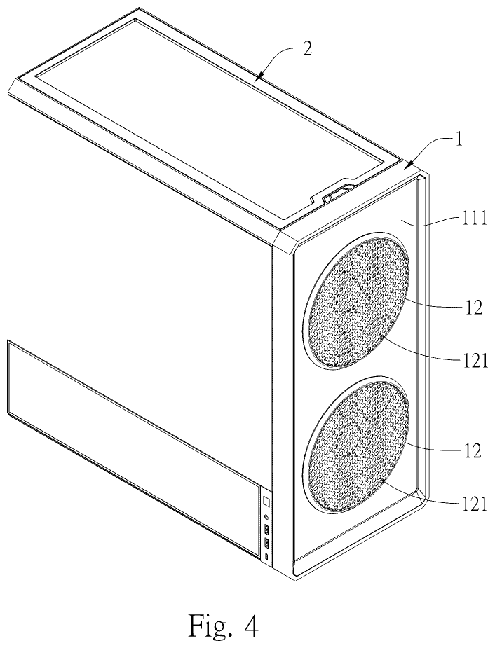

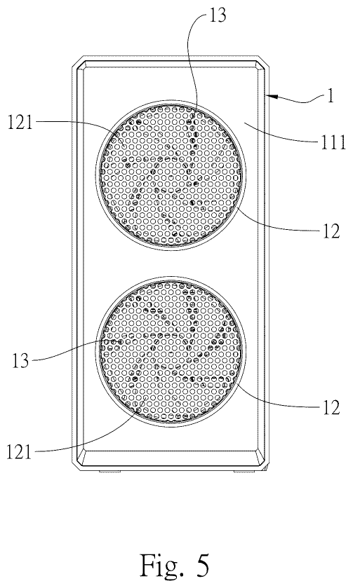

Therefore, in implementation, when the cooling fans 13 are sequentially installed within the through holes 113 on the inner surface 112 of the panel body 11, and each cover 12 on the other side of the through hole 113 is also mounted on the outer surface 111 of the panel body 11, the airflow generated by the cooling fans 13 after staring up can flow in and out through the through holes 113 and the ventilation holes 121 on the covers 12, thereby forming a heat dissipation channel within the panel body 11 on the front side of the computer case 2 (as shown in FIGS. 4 and 5).

Accordingly, the present invention has the following advantages:
1. Through the design of this invention, a panel with airflow channels can be formed on the front side of the computer case. This provides additional heat dissipation pathways beyond the conventional rear exhaust of the computer case, so that the heat accumulated inside the computer case can be exhausted quickly and effectively.
2. The present invention utilizes a front-mounted design to conceal the cooling fan within the panel body, and this structure design is simple and concise, so that the assembly or replacement could be convenient and quick. As the front-mounted cover on the panel body could be removably disassembled and replaced, combined with the design of light-transmissive panel body, the present invention could offer consumers a distinct visual experience, thereby enhancing the competitiveness of the sales of the computer case in the market.

Although the embodiments of the present invention have been described in detail, many modifications and variations may be made by those skilled in the art from the teachings disclosed hereinabove. Therefore, it should be understood that any modification and variation equivalent to the spirit of the present invention be regarded to fall into the scope defined by the appended claims.

In summary, as disclosed in the above description and attached drawings, the present invention can indeed achieve the expected object by providing a front panel structure of a computer case, which is of great practicality and industrial value.

What is claimed is:

1. A front panel structure of a computer case, configured to be assembled with a front side of the computer case to form a computer case structure, the front panel structure comprising:
a panel body having an outer surface and an inner surface, the panel body being provided with a plurality of through holes, each of the through holes penetrating the outer surface and the inner surface of the panel body;
a plurality of covers, wherein each of the covers is detachably connected to a corresponding through hole on the outer surface of the panel body to close the through hole, and each cover is provided with a plurality of ventilation holes; and
a plurality of cooling fans sequentially located on the inner surface of the panel body, wherein each of the cooling fans is aligned opposite each of the through holes to allow airflow generated by the cooling fan after starting to flow in and out through the through holes and the covers.

2. The front panel structure of the computer case according to claim 1, wherein each of the through holes is provided with at least one engaging portion, and each of the covers is provided with a corresponding engaging portion for correspondingly engaging the engaging portion, thereby enabling each cover to be detachably and securely mounted to the outer surface of the panel body.

3. The front panel structure of the computer case according to claim 2, wherein the engaging portion is a protrusion on an inner wall of the through hole, and the corresponding engaging portion is an L-shaped engaging slot disposed in the cover.

4. The front panel structure of the computer case according to claim 1, further comprising an inner frame having an inner side and an outer side, wherein the outer side of the inner frame is configured to engage with the inner surface of the panel body, and the inner side of the inner frame is configured to engage with the computer case, each of the cooling fans is sequentially positioned between the outer side of the inner frame and the inner surface of the panel body, and each cooling fan is respectively aligned opposite each of the through holes, enabling the airflow generated by the cooling fan after starting to flow in and out through the through holes.

5. The front panel structure of the computer case according to claim 4, wherein the inner frame is provided with a plurality of lock holes for securing the cooling fan to the outer side of the inner frame via a locking connection.

6. The front panel structure of the computer case according to claim 2, wherein the panel body is a light-transmissive panel body.

7. The front panel structure of the computer case according to claim 2, wherein the panel body is a mirror-finish panel body.
